(19) United States
(12) Patent Application Publication
(10) Pub. No.: US 2013/0311843 A1
(43) Pub. Date: Nov. 21, 2013

(54) SCAN CONTROLLER CONFIGURED TO CONTROL SIGNAL VALUES APPLIED TO SIGNAL LINES OF CIRCUIT CORE INPUT INTERFACE

(71) Applicants: Ramesh C. Tekumalla, Breinigsville, PA (US); Priyesh Kumar, Pune (IN)

(72) Inventors: Ramesh C. Tekumalla, Breinigsville, PA (US); Priyesh Kumar, Pune (IN)

(73) Assignee: LSI Corporation, Milpitas, CA (US)

(21) Appl. No.: 13/473,099

(22) Filed: May 16, 2012

(51) Int. Cl. G01R 31/3177; G06F 11/25

(52) U.S. Cl. 714/729; 714/E11.155

(57) ABSTRACT

An integrated circuit comprises a memory or other circuit core having an input interface and an output interface, scan circuitry comprising at least one scan chain having a plurality of scan cells, and additional circuitry associated with at least one of the input interface and the output interface and testable utilizing said at least one scan chain. The scan circuitry further comprises a scan controller configured to control signal values applied to one or more signal lines of the input interface in conjunction with testing of the additional circuitry utilizing said at least one scan chain. For example, the scan controller may control signal values applied to respective address input and write enable signal lines in a manner that ensures that data written to a memory in a write operation of a given memory cycle can be read from the memory in a read operation of a subsequent memory cycle.

### BACKGROUND

Integrated circuits are often designed to incorporate scan test circuitry that facilitates testing for various internal fault conditions. Such scan test circuitry typically comprises scan chains comprising multiple scan cells. The scan cells may be implemented, by way of example, utilizing respective flip-flops. The scan cells of a given scan chain are configurable to form a serial shift register for applying test patterns at inputs to combinational logic of the integrated circuit. The scan cells of the given scan chain are also used to capture outputs from other combinational logic of the integrated circuit.

Scan testing of an integrated circuit may therefore be viewed as being performed in two repeating phases, namely, a scan shift phase in which the flip-flops of the scan chain are configured as a serial shift register for shifting in and shifting out of respective input and output scan data, and a scan capture phase in which the flip-flops of the scan chain capture scan data from combinational logic. These two repeating scan test phases are often collectively referred to as a scan test mode of operation of the integrated circuit.

Outside of the scan test mode and its scan shift and capture phases, the integrated circuit may be said to be in a functional mode of operation. Other definitions of the scan test and functional operating modes may also be used. For example, the capture phase associated with a given scan test may instead be considered part of a functional mode of operation, such that the modes include a scan shift mode having only the scan shift phase, and a functional mode that includes the capture phase.

An integrated circuit may also be configured to include built-in self-test (BIST) capabilities. Such BIST capabilities in some implementations make use of scan test circuitry and operating modes of the type described above. BIST implementations may be configured to test particular portions of an integrated circuit, such as a memory. BIST testing of integrated circuit memories is also referred to as memory BIST (MBIST). MBIST is typically used to detect faults that are internal to the memory. However, conventional MBIST arrangements are unable to detect faults associated with functional data and address paths at the memory interface. This is because the data and address inputs applied during MBIST are provided to the memory interface by a test controller, with the functional data and address paths bypassed. Undetected faults associated with these functional paths at the memory interface can cause the integrated circuit to fail in the field.

It is possible to utilize scan circuitry to test the functional data and address paths. Examples of techniques of this type are disclosed in U.S. patent application Ser. No. 13/445,308, filed Apr. 12, 2012 and entitled “Scan-Based Capture and Shift of Interface Functional Signal Values in Conjunction with Built-In Self-Test,” which is commonly assigned herewith and incorporated by reference herein.

### SUMMARY

One or more illustrative embodiments of the invention provide integrated circuits in which combinational logic associated with respective input and output interfaces of a memory interface or other type of circuit core interface can be tested and the results observed via one or more scan chains. In conjunction with the scan testing, signal values applied to signal lines of the circuit core interface are controlled in a manner that facilitates the scan testing of the combinational logic. For example, in an embodiment in which the circuit core comprises a memory, scan testing of functional data and address paths of the memory is facilitated by controlling signal values on address input and write enable signal lines of an input interface of the memory. Such arrangements can prevent the address input and write enable signal lines from fluctuating after test data is written to the memory but before that test data can be read from the memory. As a result, more effective use can be made of memory contents during scan testing, so as to reduce test pattern count and test time.

In one embodiment, an integrated circuit comprises a memory or other circuit core having an input interface and an output interface, scan circuitry comprising at least one scan chain having a plurality of scan cells, and additional circuitry associated with at least one of the input interface and the output interface and testable utilizing said at least one scan chain. The scan circuitry further comprises a scan controller configured to control signal values applied to one or more signal lines of the input interface in conjunction with testing of the additional circuitry utilizing said at least one scan chain.

By way of example, the circuit core may comprise a memory, the input interface may comprise data input, address input and write enable signal lines, and the output interface may comprise data output signal lines. In an embodiment of this type, the scan controller may be configured to control signal values applied to respective ones of the address input and write enable signal lines in a manner that ensures that data written to the memory in a write operation of a given memory cycle can be read from the memory in a read operation of a subsequent memory cycle.

The additional circuitry that is testable utilizing the one or more scan chains may comprise input combinational logic associated with an input functional path to the input interface of the circuit core, and output combinational logic associated with an output functional path from the output interface of the circuit core. In such an arrangement, the one or more scan chains may include a first scan chain comprising scan cells coupled to respective signal lines of the input combinational logic, and a second scan chain comprising scan cells coupled to respective signal lines of the output combinational logic. The first scan chain is configured to launch test input signal values onto the respective signal lines of the input combinational logic in accordance with a test pattern shifted into the first scan chain. The second scan chain is configured to capture test output signal values from the respective signal lines of the output combinational logic and to shift out the captured test output signal values.

Embodiments of the invention can provide improved fault coverage in testing of integrated circuits without significantly increasing the cost or complexity of these devices. For example, by allowing memory contents to be more effectively utilized during scan testing of combinational logic associated with memory input and output interfaces, the number of required test patterns can be significantly reduced, resulting in a substantial reduction in integrated circuit test time.

### BRIEF DESCRIPTION OF THE DRAWINGS

FIG. 1 is a block diagram showing an integrated circuit configured for scan testing of combinational logic associated with input and output interfaces of a circuit core in an illustrative embodiment.

FIGS. 2, 3 and 4 show more detailed views of portions of the FIG. 1 integrated circuit in an illustrative embodiment in which the circuit core comprises a memory.

FIG. 5 is a timing diagram illustrating the operation of a scan controller of FIG. 4.

FIG. 6 shows one possible alternative embodiment of a portion of the FIG. 4 circuitry.

FIG. 7 illustrates a testing system that may be utilized in testing the integrated circuit of FIG. 1.

FIG. 8 is a block diagram of a processing system for generating an integrated circuit design comprising circuitry of the type illustrated in FIGS. 2-4 and 6.

### DETAILED DESCRIPTION

Embodiments of the invention will be illustrated herein in conjunction with exemplary integrated circuits comprising scan test circuitry for supporting scan testing of functional logic or other additional circuitry associated with one or more circuit cores of those integrated circuits. It should be understood, however, that embodiments of the invention are more generally applicable to any testing system, design system or associated integrated circuit in which it is desirable to provide improved scan testing of additional circuitry associated with a memory or other integrated circuit core.

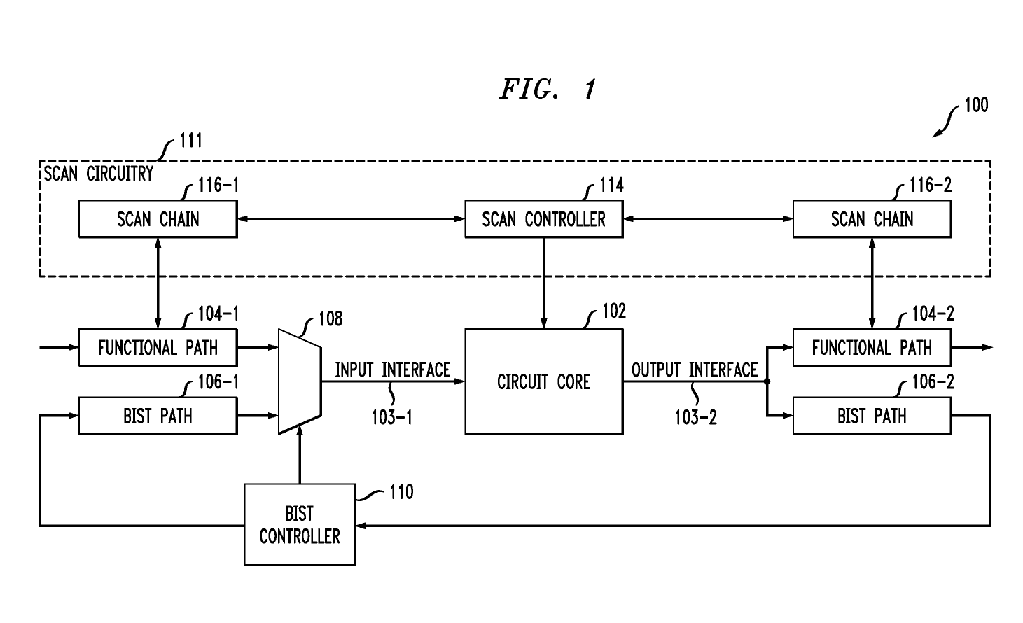

FIG. 1 shows an embodiment of the invention in which an integrated circuit 100 comprises a circuit core 102. The circuit core 102 has an input interface 103-1 and an output interface 103-2. The input interface 103-1 is selectively connectable to one of an input functional path 104-1 and an input BIST path 106-1. The output interface 103-2 is coupled to an output functional path 104-2 and an output BIST path 106-2. An input multiplexer 108 controls the selection of one of the input functional path 104-1 and the input BIST path 106-1 for application to the input interface 103-1, responsive to a control signal from a BIST controller 110. Thus, the multiplexer 108 is configured to select between application of functional input signals from the input functional path 104-1 to the input interface 103-1, and application of test input signals from the input BIST path 106-1 to the input interface 103-1.

It should be noted that the input functional and BIST paths 104-1 and 106-1 may each comprise multiple parallel signal lines, and thus multiplexer 108 may comprise a bank of two-to-one multiplexers each configured to switch between one of the functional signal lines and a corresponding one of the BIST signal lines. In an embodiment in which circuit core 102 comprises a memory, the input functional signal lines may comprise both data input and address input signal lines, as well as other types of signal lines, such as write enable signal lines. Multiplexer 108 is an example of what is more generally referred to herein as “selection circuitry,” and numerous alternative arrangements of such circuitry may be used to switch between functional and BIST paths in other embodiments.

The input and output BIST paths 106, multiplexer 108 and BIST controller 110 collectively comprise one example of what is more generally referred to herein as “BIST circuitry.” Such circuitry in the present embodiment is configured for testing of the circuit core 102 between its input and output interfaces 103 in a BIST mode of operation of the integrated circuit 100. Thus, in the BIST mode of operation, test input signals from the BIST controller 110 are applied to the input interface 103-1 via BIST path 106-1 and multiplexer 108, and corresponding test output signals are returned to the BIST controller 110 via the output BIST path 106-2. Numerous other types of BIST circuitry and BIST testing may be used in other embodiments.

It is also to be appreciated that, although illustrated in FIG. 1 as being configured for BIST testing, the integrated circuit 100 does not require BIST functionality, and in other embodiments the BIST circuitry may be eliminated.

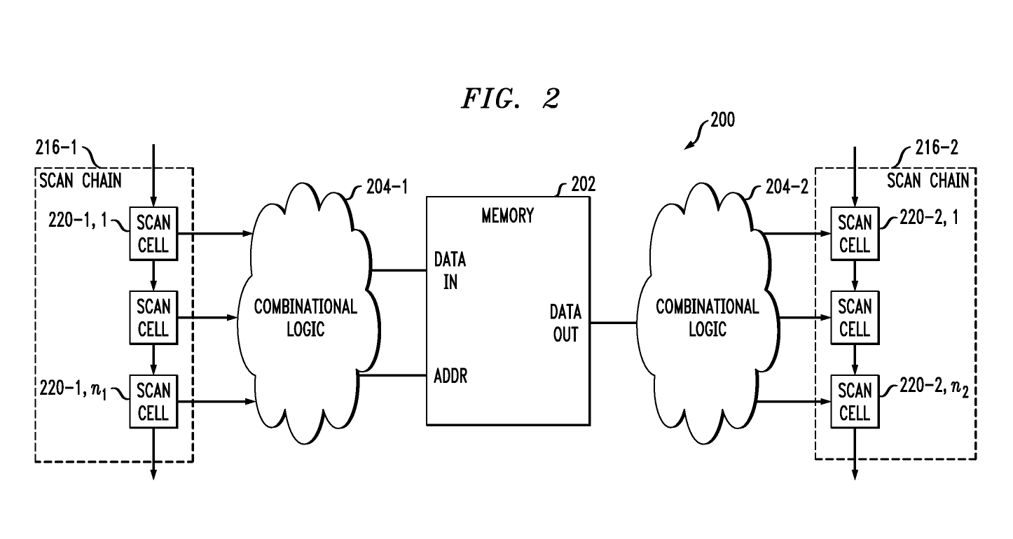

The integrated circuit 100 in the present embodiment further includes scan circuitry 111 comprising first and second scan chains 116-1 and 116-2, each having a plurality of scan cells, and a scan controller 114 coupled to the scan chains and to the circuit core 102. Additional circuitry associated with the input interface 103-1 and the output interface 103-2 of the circuit core 102 is testable utilizing the scan chains 116 of the scan circuitry 111, under the control of the scan controller 114. As will be described in more detail below in conjunction with FIGS. 2 through 6, the scan controller 114 is configured to control signal values applied to one or more signal lines of the input interface 103-1 in conjunction with testing of the additional circuitry utilizing the scan chains 116. This signal value control considerably facilitates scan testing of the additional circuitry. For example, in an embodiment in which the circuit core comprises a memory, scan testing of functional data and address paths of the memory is facilitated by controlling signal values on address input and write enable signal lines of an input interface of the memory, so as to prevent the address input and write enable signal lines from fluctuating after test data is written to the memory but before that test data can be read from the memory, thereby allowing more effective use to be made of memory contents during scan testing, and reducing test pattern count and test time.

The particular configuration of integrated circuit 100 as shown in FIG. 1 is exemplary only, and the integrated circuit 100 in other embodiments may include other elements in addition to or in place of those specifically shown, including one or more elements of a type commonly found in a conventional implementation of such an integrated circuit. For example, various elements of the integrated circuit 100 may be implemented, by way of illustration only and without limitation, utilizing a microprocessor, central processing unit (CPU), digital signal processor (DSP), application-specific integrated circuit (ASIC), field-programmable gate array (FPGA), or other types of data processing circuitry, as well as portions or combinations of these and other circuitry arrangements.

The integrated circuit 100 may be configured for installation on a circuit board or other mounting structure in a computer, server, mobile telephone or other type of communication device. Such communication devices may also be viewed as examples of what are more generally referred to herein as “processing devices.” The latter term is also intended to encompass storage devices, as well as other types of devices comprising data processing circuitry.

The circuit core 102 in integrated circuit 100 of FIG. 1 may be any type of circuit core that has additional circuitry associated with at least one of its input interface 103-1 and output interface 103-2 where the additional circuitry is testable utilizing at least one of the scan chain 116. Such additional circuitry may comprise combinational logic associated with one or more of the functional paths 104.

The circuit core in embodiments to be described in conjunction with FIGS. 2 through 6 comprises a memory 202 within circuitry 200 which is assumed to be part of the integrated circuit 100. In other embodiments, other types of circuit cores may be subject to scan testing using the techniques disclosed herein. As another example, circuit cores in another embodiment may comprise respective read channel and additional cores of a system-on-chip (SOC) integrated circuit in a hard disk drive (HDD) controller application, designed for reading and writing data from one or more magnetic storage disks of an HDD. In other embodiments, the circuit cores having input and output interfaces associated with additional circuitry that is subject to testing utilizing one or more scan chains may comprise other types of functional logic circuitry, in any combination.

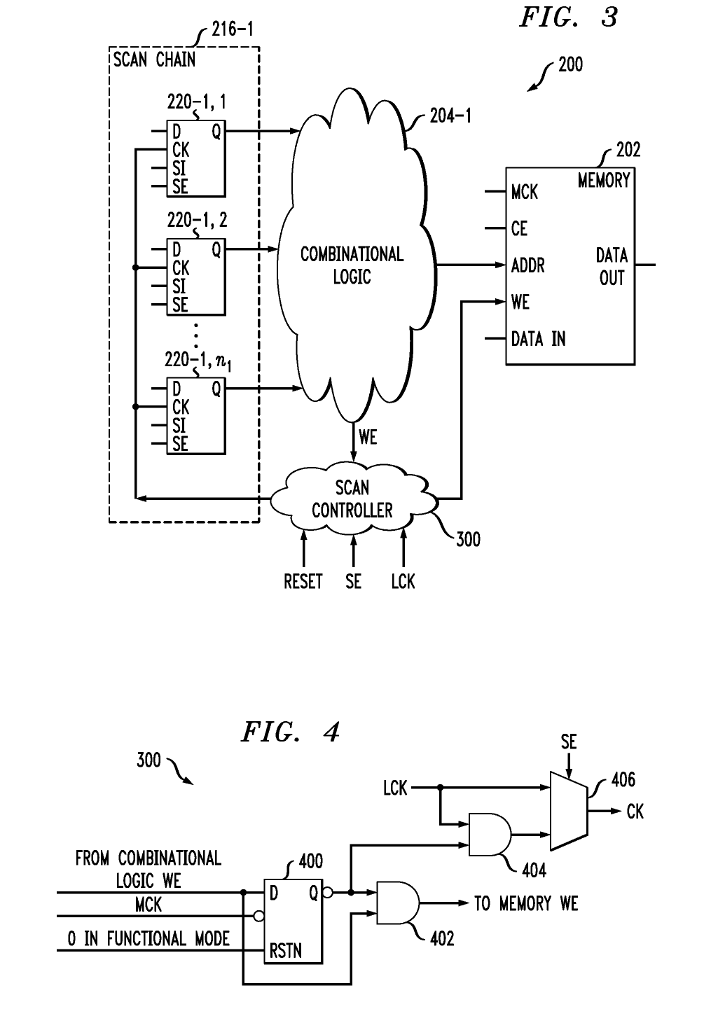

Referring now to FIG. 2, circuitry 200 comprising memory 202 includes input combinational logic 204-1 associated with an input functional path to the input interface of the memory 202, and output combinational logic 204-2 associated with an output functional path from the output interface of the memory. The input interface in this embodiment comprises data input and address input signal lines, denoted DATA IN and ADDR, and will typically also include additional signal lines not expressly shown in this figure, such as write enable signal lines, as will be described in conjunction with FIG. 3. The output interface comprises data output signal lines denoted DATA OUT.

The scan circuitry in this embodiment illustratively comprises a first scan chain 216-1 of length n₁ that includes scan cells 220-1,1 through 220-1,n₁, and a second scan chain 216-2 of length n₂ that includes scan cells 220-2,1 through 220-2,n₂. The use of two scan chains in this figure is by way of example only. A large number of additional scan chains may be included in a given integrated circuit implementation, arranged for testing additional combinational logic, as will be appreciated by those skilled in the art.

The scan cells 220 of the first scan chain 216-1 are coupled to respective signal lines of the input combinational logic 204-1, and the scan cells of the second scan chain 220 are coupled to respective signal lines of the output combinational logic 204-2.

The first scan chain 216-1 is configured to launch test input signal values onto the respective signal lines of the input combinational logic 204-1 in accordance with a test pattern shifted into the first scan chain.

The second scan chain 216-2 is configured to capture test output signal values from the respective signal lines of the output combinational logic 204-2 and to shift out the captured test output signal values.

Although not illustrated in FIG. 2, a scan controller such as scan controller 114 is assumed to be coupled to the scan chains 216 and to direct their operation in a manner that will be described in greater detail below. The scan controller in the present embodiment generally controls signal values applied to respective ones of the address input and write enable signal lines of the input interface of the memory 202 in a manner that ensures that data written to the memory in a write operation of a given memory cycle can be read from the memory in a read operation of a subsequent memory cycle.

FIG. 3 shows an exemplary scan controller 300 of the type described above. The scan controller 300 receives a write enable signal denoted WE from the combinational logic 204-1, and receives additional signals from other sources, including a logic clock signal denoted LCK, a scan enable signal denoted SE, and a reset signal. The input interface of the memory 202 further comprises, in addition to the data and address inputs previously described, inputs for receiving a controlled write enable signal WE, a memory clock signal MCK, and a chip enable signal CE. The LCK and MCK clock signals may both be provided from a common clock source, and may actually constitute the same clock signal, but are separately designated herein for clarity of illustration. For purposes of the present embodiments, it will be assumed without limitation that the LCK and MCK clock signals refer to the same clock signal.

It should be noted that designations such as WE, SE, LCK, MCK, DATA IN and ADDR will be used herein to refer to signals as well as the corresponding inputs, outputs or signal lines that are associated with those signals.

Each of the scan cells 220 of scan chain 216-1 comprises a data input D, a data output Q coupled to a corresponding signal line of the combinational logic 204-1, a clock input CK coupled to an output of the scan controller 300, a scan enable input SE, a scan input SI and a scan output SO. For a given scan cell that is neither an initial cell nor a final cell of the scan chain, its scan input is adapted for coupling to a scan output of a previous one of the scan cells in the scan chain, and its scan output is adapted for coupling to a scan input of a subsequent one of the scan cells in the scan chain.

Although not expressly shown in the figure, it is assumed that an initial scan cell of the scan chain 216-1 has its scan input coupled to a scan output of the scan controller 300, and a final scan cell of the scan chain 216-1 has its scan output coupled to a scan input of the scan controller 300. The scan chain 216-2 and any other scan chains of the scan circuitry are assumed to be configured in a manner similar to scan chain 216-1.

A scan shift control signal is utilized to cause the scan cells 220 of a given scan chain 216 to form a serial shift register. The scan shift control signal in the present embodiment comprises the above noted SE signal, such that the scan cells of the given scan chain form the serial shift register responsive to the SE signal being at a first designated logic level (e.g., a logic “1” level) and the scan cells capture functional data when the SE signal is at a second designated logic level (e.g., a logic “0” level). As noted previously, these conditions are also referred to as respective scan shift and scan capture phases. Each such phase spans multiple clock cycles, also referred to as shift or capture clock cycles depending upon the phase in which they occur.

A single SE signal may be used to control all of the scan cells of each scan chain 216. The SE signal in such an embodiment controls configuration of scan cells of a scan chain to form a serial shift register in conjunction with scan testing of the combinational logic 204-1 and 204-2 associated with the respective input and output interfaces of the memory 202.

The scan controller 300 in the present embodiment is configured to control the write enable signal value applied to the write enable input of the memory 202, by holding the controlled write enable signal WE at an inactive level after performance of a write operation in a given memory cycle, such that additional write operations cannot be performed while the controlled write enable signal WE remains at the inactive level.

The scan controller 300 is further configured to control a clock signal CK applied to at the scan cells 220 of the scan chain 216-1, by disabling the clock signal CK after performance of a write operation in a given memory cycle, such that corresponding ones of the address input signal lines are held at particular values utilized in the write operation while the clock signal CK is disabled. It is assumed in this regard that the scan cells for which the clock signal CK is disabled include the scan cells that drive signals lines of the combinational logic that control the address inputs of the memory 202.

Although the scan cells 220 of the scan chain 216-1 are shown in the figure as all receiving the same clock signal CK, in other embodiments a given scan chain may be associated with multiple clock domains, such that different subsets of the scan cells of the scan chain receive clock signals associated with their respective clock domains. The disclosed techniques can be adapted in a straightforward manner to accommodate such multiple clock domain arrangements.

The above-noted functionality of scan controller 300 is effective to control the memory interface during scan testing of the combinational logic 204-1 and 204-2 such that if a particular memory location is written with test data, the corresponding memory contents can be immediately read out so that the test pattern is made more effective in detecting faults on the paths leading to the particular memory location. More particularly, the scan controller holds the signal values on the address input signal lines while also controlling the write enable signal line to temporarily disable subsequent writes, such that the same contents written during one memory cycle can be read out in the next memory cycle. This freezing of the address input signal lines and deactivation of the write enable signal line ensures that combinational logic faults that are activated by a given test pattern can be accurately and efficiently detected using that same test pattern.

Without such scan controller functionality, it can be difficult for a test generation tool to provide test patterns that detect faults in the combinational logic associated with the input and output interfaces of the memory, because the address input and write enable signal lines may change during a particular test pattern in an unpredictable manner. As a result, the test generation tool may be required to keep track of memory contents across multiple test patterns, which unduly increases test pattern complexity and test time. These and other problems are avoided in the present embodiment by the inclusion of scan circuitry comprising scan controller 300 configured as described above.

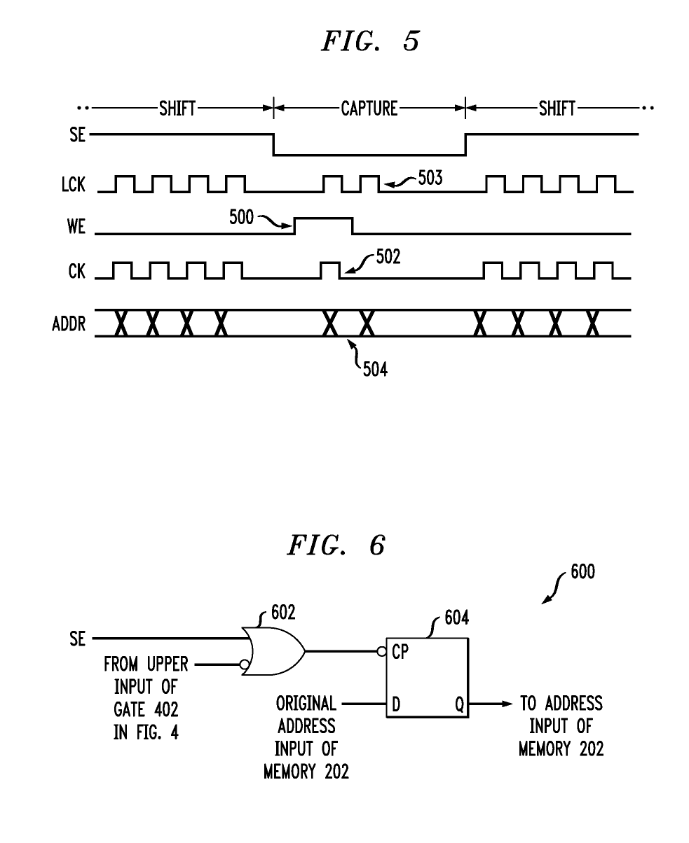

FIG. 4 shows a more detailed view of at least a portion of the scan controller 300 in one embodiment. The scan controller 300 as shown comprises a flip-flop 400, logic gates 402 and 404, and a multiplexer 406. The flip-flop 400 has a data input D adapted to receive the write enable signal WE from the combinational logic 204-1. The logic gate 402, illustratively implemented as a two-input AND gate in this embodiment, has a first input coupled to an inverted data output Q of the flip-flop 400, a second input adapted to receive the write enable signal WE, and an output providing a controlled write enable signal for application by the scan controller 300 to the write enable input of the memory 202.

The multiplexer 406 comprises a two-to-one multiplexer having a first input adapted to receive the clock signal LCK, which as noted above is assumed to correspond to the clock signal MCK in the present embodiment, a second input adapted to receive the clock signal LCK gated based at least in part on the write enable signal WE, an output providing a controlled clock signal CK to the clock signal inputs of respective ones of the scan cells 220 of the scan chain 216-1, and a select line driven by the scan enable signal SE.

The flip-flop 400 has an active low clock input adapted to receive the MCK clock signal that is also applied to the clock input of the memory 202, and also has an active low reset input that receives a designated signal value, in this embodiment a logic “0” level, during a functional mode of operation of the integrated circuit 100.

Thus, in the functional mode of operation, the flip-flop 400 is held in a reset state, such that the inverted data output Q is held at a logic “1” level. As a result, gates 402 and 404 effectively become transparent in the functional mode, such that the WE signal from the combinational logic 204-1 passes unaltered through gate 402 to the WE input signal line of the memory 202, and the LCK clock signal passes unaltered through gate 404 and multiplexer 406 to the CK inputs of the scan cells 220.

As indicated above, the scan controller 300 as shown in FIG. 4 is operative to temporarily freeze the address input signal lines ADDR to the respective signal values that these lines take on in a given write operation directed to the memory 202, while also temporarily preventing additional assertions of the controlled write enable signal subsequent to an initial detected assertion of the write enable signal that occurs within a given capture cycle of a scan capture phase.

This process is illustrated in the timing diagram of FIG. 5, which shows the signals SE, LCK, WE, CK and ADDR for a given capture phase and portions of the shift phases that precede and follow that capture phase. It was noted previously that, in the present embodiment, when the scan enable signal SE is at a logic “1” level, the scan circuitry is in a scan shift phase and the scan cells 220 of the scan chains 216 are configured as a serial shift register, and when the scan enable signal SE is at a logic “0” level, the scan circuitry is in a scan capture phase and the scan cells 220 of the scan chains 216 capture scan data from combinational logic.

In the scan shift phases, multiplexer 406 selects its upper input, corresponding to the LCK clock signal, for application to the CK inputs of the scan cells 220, and thus the CK signal in FIG. 5 follows the LCK signal during the scan shift phases. However, in the capture phase, SE is low and the multiplexer 406 selects its lower input, corresponding to the output of logic gate 404, for application to the CK inputs of the scan cells 220.

Thus, the CK signal in a given capture clock cycle of the scan capture phase depends on the state of the write enable signal WE in a previous capture clock cycle of that scan capture phase. More particularly, if the write enable signal WE is at a logic “1” during a capture clock cycle, CK will be disabled by being held low for at least the next capture clock cycle. Also, the controlled write enable signal applied to the write enable input of the memory 202 via logic gate 402 will be at a logic “0” level for at least the next capture clock cycle.

The scan controller 300 therefore detects in flip-flop 400 the assertion 500 of the write enable signal WE during a capture clock cycle corresponding to capture clock pulse 502. As a result, the upper input of logic gate 402 is at a logic “0” level, and the next clock pulse 503 of the LCK signal does not cause a corresponding pulse at CK because it is blocked by logic gate 404. Also, the gate 402 prevents the write enable signal WE from being applied to the write enable input of memory 202. This ensures that address input signal values 504 associated with clock pulse 502 are maintained, such that the data written to the memory 202 using the address input signal values 504 can be read out properly from the same location in the memory in a subsequent clock cycle.

It should be noted that the CK signal is disabled after clock pulse 502 even though the LCK signal includes clock pulse 503 in the capture clock cycle following the one in which the write enable signal WE was asserted.

The circuitry associated with the scan controller 300 as illustrated in FIG. 4 can be integrated into the combinational logic 204 around the memory 202. As noted above, this scan controller circuitry of FIG. 4 is essentially transparent in the functional mode of operation and is active only in the scan test mode of operation. The reset signal applied as an input to the scan controller 300 can come from an external pin or may be a control signal generated within the integrated circuit 100. The scan enable and reset signals are configured to assume appropriate default values in the functional mode.

Another embodiment of a portion of the scan controller 300 of FIG. 4 is illustrated in FIG. 6. In this embodiment, logic gate 404 and multiplexer 406 are replaced by circuitry 600 comprising a logic gate 602, illustratively a two-input OR gate with an inverting lower input, and a latch 604, both of which are assumed to be replicated for each of the address input signal lines of the memory 202. Thus, the circuitry 600 comprises a plurality of latches 604 having respective data paths arranged in series with respective ones of the address input signal lines. The logic gate 602 has a first input adapted to receive the scan enable signal SE, a second input adapted to receive the same input as the upper input of logic gate 402, and an output coupled to control inputs of respective ones of the latches 604.

The latches 604 in the present embodiment are negative level-sensitive latches, although other types of latches could be used. These latches can be controllably configured to maintain the respective address input signal line values associated with a given write operation as indicated at 504 in the FIG. 5 timing diagram, so as to ensure proper readout of the corresponding location in the memory 202 in a subsequent clock cycle. A given latch 604 is in an “open” state such that its data input D passes to its data output Q when the scan enable signal SE is at a logic “0” level and the write enable signal WE is at a logic “1” level. Otherwise the latch is in a “closed” state and its output is retained so as to maintain the corresponding address input signal value.

It is to be appreciated that the particular circuitry and timing arrangements shown in FIGS. 2 through 6 are presented by way of illustrative example only, and numerous alternative arrangements of scan circuitry may be used to implement the described scan testing functionality. This functionality can be implemented in one or more of the illustrative embodiments without any significant negative impact on integrated circuit area requirements or functional timing requirements.

Other embodiments can replicate the scan controller circuitry for each of a plurality of different memories of a given integrated circuit. Also, the particular number of capture clock cycles for which the write enable signal is made inactive and the address input signal values are maintained may be varied in other embodiments.

Captured signal values shifted out from the scan chains may be provided via the scan controller 114 or 300 to a chip-level pin, or processed internally by the scan controller or other scan circuitry of the integrated circuit 100.

Although scan cells are shown for only two scan chains in FIG. 2, a typical implementation will include many more scan cells and scan chains. Also, a given integrated circuit may comprise multiple memories like memory 202, at least a subset of which may be of different sizes. For example, in one illustrative implementation of integrated circuit 100, there may be as many as 50 separate memories of different sizes.

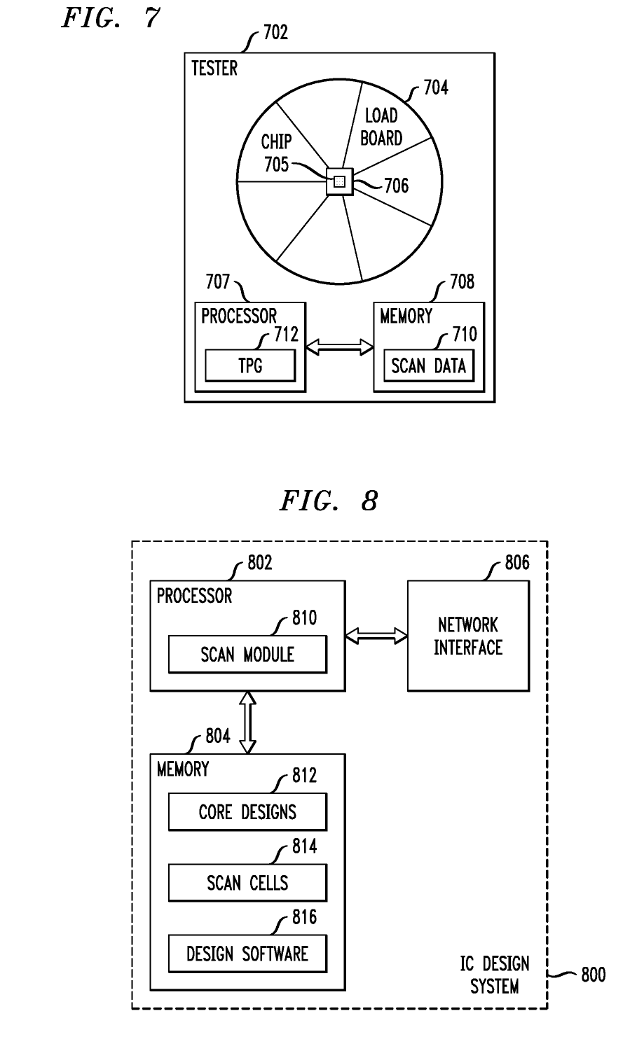

Scan testing in embodiments of the invention may make use of external or internal testers, or combinations thereof. FIG. 7 shows an example of an external tester 702 that comprises a load board 704. An integrated circuit 705 to be subject to scan testing using the techniques disclosed herein is installed in a central portion 706 of the load board 704. The tester 702 also comprises processor and memory elements 707 and 708 for executing stored program code. In the present embodiment, processor 707 is shown as implementing a test pattern generator (TPG) denoted by reference numeral 712. Associated scan data 710 is stored in memory 708.

Numerous alternative testers may be used to perform scan testing of an integrated circuit as disclosed herein. Also, as indicated previously, in alternative embodiments one or more portions of an external tester may be incorporated into the integrated circuit itself, as in BIST arrangement.

The insertion of scan chains, scan controllers and other associated circuitry in a given integrated circuit design may be performed in a processing system 800 of the type shown in FIG. 8. Such a processing system in this embodiment more particularly comprises a design system configured for use in designing integrated circuits such as integrated circuit 100 to include scan cells for testing combinational logic associated with input and output interfaces of a circuit core. The system 800 comprises a processor 802 coupled to a memory 804. Also coupled to the processor 802 is a network interface 806 for permitting the processing system to communicate with other systems and devices over one or more networks. The network interface 806 may therefore comprise one or more transceivers. The processor 802 implements a scan module 810 for supplementing core designs 812 with scan cells 814 configured for testing of combinational logic associated with circuit core interfaces, in conjunction with utilization of integrated circuit design software 816. By way of example, the scan circuitry comprising scan chains 216 and scan controller 300 may be generated in system 800 using an RTL description and then synthesized to gate level using a specified technology library.

Elements such as 810, 812, 814 and 816 are implemented at least in part in the form of software stored in memory 804 and processed by processor 802. For example, the memory 804 may store program code that is executed by the processor 802 to implement particular scan chain functionality of module 810 within an overall integrated circuit design process. The memory 804 is an example of what is more generally referred to herein as a computer-readable medium or other type of computer program product having computer program code embodied therein, and may comprise, for example, electronic memory such as RAM or ROM, magnetic memory, optical memory, or other types of storage devices in any combination. The processor 802 may comprise a microprocessor, CPU, ASIC, FPGA or other type of processing device, as well as portions or combinations of such devices.

As indicated above, embodiments of the invention may be implemented in the form of integrated circuits. In a given such integrated circuit implementation, identical die are typically formed in a repeated pattern on a surface of a semiconductor wafer. Each die includes one or more circuit cores and scan circuitry as described herein, and may include other structures or circuits. The individual die are cut or diced from the wafer, and then each die is packaged as an integrated circuit. One skilled in the art would know how to dice wafers and package die to produce integrated circuits. Integrated circuits so manufactured are considered embodiments of this invention.

Again, it should be emphasized that the embodiments of the invention as described herein are intended to be illustrative only. For example, other embodiments of the invention can be implemented using a wide variety of other types of circuit cores, scan controllers and scan chains, with different types and arrangements of scan cells, as well as different types and arrangements of operating modes and control signaling, than those included in the embodiments described herein. These and numerous other alternative embodiments within the scope of the following claims will be readily apparent to those skilled in the art.

What is claimed is:

1. An integrated circuit comprising:
a circuit core having an input interface and an output interface;
scan circuitry comprising at least one scan chain having a plurality of scan cells; and
additional circuitry associated with at least one of the input interface and the output interface of the circuit core and testable utilizing said at least one scan chain;
the scan circuitry further comprising a scan controller configured to control signal values applied to one or more signal lines of the input interface in conjunction with testing of the additional circuitry utilizing said at least one scan chain.

2. The integrated circuit of claim 1 wherein said additional circuitry that is testable utilizing said at least one scan chain comprises:
input combinational logic associated with an input functional path to the input interface of the circuit core; and
output combinational logic associated with an output functional path from the output interface of the circuit core.

3. The integrated circuit of claim 2 wherein said at least one scan chain comprises:
a first scan chain comprising scan cells coupled to respective signal lines of the input combinational logic; and
a second scan chain comprising scan cells coupled to respective signal lines of the output combinational logic.

4. The integrated circuit of claim 3 wherein the first scan chain is configured to launch test input signal values onto the respective signal lines of the input combinational logic in accordance with a test pattern shifted into the first scan chain, and wherein the second scan chain is configured to capture test output signal values from the respective signal lines of the output combinational logic and to shift out the captured test output signal values.

5. The integrated circuit of claim 1 wherein the circuit core comprises a memory, the input interface comprises data input, address input and write enable signal lines, and the output interface comprises data output signal lines.

6. The integrated circuit of claim 5 wherein the scan controller controls signal values applied to respective ones of the address input and write enable signal lines in a manner that ensures that data written to the memory in a write operation of a given memory cycle can be read from the memory in a read operation of a subsequent memory cycle.

7. The integrated circuit of claim 5 wherein the scan controller is configured to control a write enable signal value applied to the write enable input of the memory, and wherein the scan controller controls the write enable signal by holding the write enable signal at an inactive level after performance of a write operation in a given memory cycle, such that additional write operations cannot be performed while said write enable signal remains at the inactive level.

8. The integrated circuit of claim 5 wherein the scan controller is configured to control a clock signal applied to at least a subset of the scan cells of said at least one scan chain, and wherein the scan controller controls the clock signal by disabling the clock signal after performance of a write operation in a given memory cycle, such that corresponding ones of the address input signal lines are held at particular values utilized in said write operation while said clock signal is disabled.

9. The integrated circuit of claim 5 wherein the scan controller is configured to control a plurality of latches having respective data paths arranged in series with respective ones of the address input signal lines.

10. The integrated circuit of claim 5 wherein the scan controller comprises:
a flip-flop having a data input adapted to receive a write enable signal from the additional circuitry; and
a logic gate having a first input coupled to an inverted data output of the flip-flop, a second input adapted to receive the write enable signal, and an output providing a controlled write enable signal for application to a write enable input of the memory;
wherein the flip-flop has an active low clock input adapted to receive a clock signal that is also applied to a clock input of the memory; and
wherein the flip-flop has a reset input that receives a designated signal value during a functional mode of operation.

11. The integrated circuit of claim 5 wherein the scan controller comprises:
a multiplexer having a first input adapted to receive an input clock signal that is also applied to the memory, a second input adapted to receive the clock signal gated based at least in part on a write enable signal, an output providing a controlled clock signal to clock signal inputs of respective ones of the scan cells of said at least one scan chain, and a select line driven by a scan enable signal.

12. The integrated circuit of claim 5 wherein the scan controller comprises:
a plurality of latches having respective data paths arranged in series with respective ones of the address input signal lines; and
logic circuitry controlling states of the latches responsive at least in part to scan enable and write enable signals.

13. A processing device comprising the integrated circuit of claim 1.

14. A method for use in an integrated circuit comprising a circuit core having an input interface and an output interface, the method comprising:
testing additional circuitry associated with at least one of the input interface and the output interface of the circuit core, utilizing at least one scan chain having a plurality of scan cells; and
controlling signal values applied to one or more signal lines of the input interface in conjunction with said testing.

15. The method of claim 14 wherein the circuit core comprises a memory, the input interface comprises data input, address input and write enable signal lines, and the output interface comprises data output signal lines.

16. The method of claim 15 wherein the controlling step comprises controlling signal values applied to respective ones of the address input and write enable signal lines in a manner that permits data written to the memory in a write operation of a given memory cycle to be read from the memory in a read operation of a subsequent memory cycle.

17. The method of claim 15 wherein the controlling step comprises controlling a write enable signal value applied to the write enable input of the memory, by holding the write enable signal at an inactive level after performance of a write operation in a given memory cycle, such that additional write operations cannot be performed while said write enable signal remains at the inactive level.

18. The method of claim 15 wherein the controlling step comprises controlling a clock signal applied to at least a subset of the scan cells of said at least one scan chain, by disabling the clock signal after performance of a write operation in a given memory cycle, such that corresponding ones of the address input signal lines are held at particular values utilized in said write operation while said clock signal is disabled.

19. The method of claim 15 wherein the controlling step comprises controlling a plurality of latches having respective data paths arranged in series with respective ones of the address input signal lines.

20. A computer-readable storage medium having computer program code embodied therein, wherein the computer program code when executed causes the integrated circuit to perform the steps of the method of claim 14.

21. A processing system comprising:
a processor; and
a memory coupled to the processor and configured to store information characterizing an integrated circuit design comprising at least one circuit core having input and output interfaces;
wherein the processing system is configured to provide, within the integrated circuit design, scan circuitry comprising at least one scan chain having a plurality of scan cells, and additional circuitry associated with at least one of the input interface and the output interface of the circuit core and testable utilizing said at least one scan chain;
the scan circuitry further comprising a scan controller configured to control signal values applied to one or more signal lines of the input interface in conjunction with testing of the additional circuitry utilizing said at least one scan chain.
